(19) United States
(12) Patent Application Publication
(10) Pub. No.: US 2025/0139310 A1
(43) Pub. Date: May 1, 2025

(54) ARTIFICIAL INTELLIGENCE ASSISTED ENGINEERING AND DESIGN

(71) Applicant: Vixiv, Inc., Cincinnati, OH (US)

(72) Inventors: Aaron Chow, Cincinnati, OH (US); Zach Beller, Cincinnati, OH (US)

(73) Assignee: Vixiv, Inc., Cincinnati, OH (US)

(21) Appl. No.: 18/933,646

(22) Filed: Oct. 31, 2024

Related U.S. Application Data
(60) Provisional application No. 63/595,124, filed on Nov. 1, 2023.

(51) Int. Cl. G06F 30/10; G06F 30/23; G06F 30/27; G06T 17/20

(52) U.S. Cl. CPC G06F 30/10; G06F 30/27; G06F 30/23; G06T 17/20

(57) ABSTRACT

A system for designing three-dimensional (3-D) structures that includes a central artificial intelligence (AI) system with a computer processor, a communications module, and memory for storing a central training database and AI models. Also included is a software application run on a computing device, the app including a training database and AI models. The central AI system receives structural data from a fabricating device or a testing apparatus, populates a training database using the structural data, and trains the AI models using the training database. A computer-implemented method for designing 3-D structures that includes receiving an external geometry and a set of design parameters for a structure, selecting a shape for a volumetric unit, creating a render of the structure, solving for the performance of the render, determining if the render meets the design parameters, determining if the render is optimized, and generating a solution for the structure.

### CROSS-REFERENCE TO RELATED APPLICATIONS

This application claims priority to U.S. Provisional Patent Application No. 63/595,124, filed Nov. 1, 2023, which is hereby incorporated by reference herein in its entirety.

### BACKGROUND OF THE INVENTION

### Field of the Invention

Embodiments of the disclosed invention relate to systems and methods for implementing artificial intelligence assisted engineering and design of tools, parts, assemblies, and components.

### Relevant Background

Traditional three-dimensional (3-D) structure design and engineering has been limited by the number of design parameters that can be concurrently considered. For example, a structure may be optimized for high strength with low weight. Other characteristics, however, such as impact resistance or vibrational response properties, must be addressed separately. Such disjointed design processes are inefficient because the effects of structural changes that improve certain performance characteristics could have unknown effects on others. The cascading effects of design changes cannot be assessed until after those changes are made. Accounting for multivariate design parameters in such methods requires hundreds or thousands of iterations, and rarely achieves optimal performance in the characteristics sought.

Advanced 3-D design processes are known in the art, see, e.g., U.S. patent application Ser. No. 18/816,130, filed Aug. 27, 2024 ('130 application), which is hereby incorporated herein in its entirety. However, the design processes discussed in the '130 application focus on particular uses for structures, i.e., thermofluidic energy management, and do not provide methods for generalized design of structures suitable for many different types of performance criteria.

It is clear that what is needed are generalized AI assisted 3-D structural design systems and methods that can produce novel 3-D structures capable of satisfying multiple and potentially competing performance criteria, and which further can concurrently account for multiple performance criteria as part of the same design process. Therefore, disclosed herein are systems and methods that concurrently adjust multivariate design parameters to create novel structures that meet specified design constraints, to include multiple performance characteristics. These and many other deficiencies of the prior art are addressed by one or more embodiments of the disclosed invention.

Additional advantages and novel features of this invention shall be set forth in part in the description that follows, and in part will become apparent to those skilled in the art upon examination of the following specification or may be learned by the practice of the invention.

### BRIEF DESCRIPTION OF THE DRAWINGS

Features and objects of the disclosed invention and the manner of attaining them will become more apparent, and the invention itself will be best understood, by reference to the following description of one or more embodiments taken in conjunction with the accompanying drawings attached following this description.

FIGS. 1A, 1B, and 1C depict examples of Svoxel representations of a 3-D space as used in embodiments of the disclosed invention.

FIG. 2 depicts exemplary internal Svoxel geometries as used in embodiments of the disclosed invention.

FIG. 3A depicts a voxel or subunit for 3-D modeling as used in embodiments of the disclosed invention.

FIG. 3B depicts a super voxel, Svoxel, or volumetric unit for 3-D modeling as used in embodiments of the disclosed invention.

FIG. 4 depicts an example use of FEA to characterize the shape of a structure as used in embodiments of the disclosed invention.

FIG. 5A depicts a cartesian coordinate system for geometry evolution as used in embodiments of the disclosed invention.

FIG. 5B depicts a polar coordinate system for geometry evolution as used in embodiments of the disclosed invention.

FIG. 5C depicts a spherical coordinate system for geometry evolution as used in embodiments of the disclosed invention.

FIG. 6 depicts a block diagram showing training and employment of an AI model as used in embodiments of the disclosed invention.

FIG. 7 depicts a block diagram showing a software application and central AI system as used in embodiments of the disclosed invention.

FIG. 8 depicts a flow chart showing at least a portion of a process for training an AI model as used in embodiments of the disclosed invention.

FIG. 9 depicts a flow chart showing at least a portion of a process for generating a structure as used in embodiments of the disclosed invention.

FIG. 10 depicts a flow chart showing at least a portion of a process for generating a structure as used in embodiments of the disclosed invention.

FIG. 11 depicts exemplary voxelated renders of a 3-D structure as used in embodiments of the disclosed invention.

FIG. 12 depicts an exemplary use of a hybrid voxelated render of a 3-D structure as used in embodiments of the disclosed invention.

FIG. 13 depicts an exemplary voxelated render of a 3-D structure and simulation model of the structure as used in embodiments of the disclosed invention.

FIG. 14 depicts a flow chart showing at least a portion of a process for generating a structure as used in embodiments of the disclosed invention.

FIG. 15 depicts a mass-spring-damper system as used in embodiments of the disclosed invention.

FIG. 16 depicts a block diagram showing a computing device as used in embodiments of the disclosed invention.

The Figures depict embodiments of the disclosed invention for purposes of illustration only. One skilled in the art will readily recognize from the following discussion that alternative embodiments of the structures and methods illustrated herein may be employed without departing from the principles of the invention described herein.

### Definitions

A voxel is a polygon in three-dimensional (3-D) space and is analogous to a pixel in two-dimensional (2-D) space. An arrangement of voxels can be used to approximate any 3-D structure. A voxel represents the smallest subdivision of space for a particular application and is not subdivided.

A supervoxel or Svoxel is a volumetric unit that includes one or more voxels. Similar to a voxel, a group of Svoxels can be used to approximate any 3-D structure, but an Svoxel can be subdivided and filled with an internal structure.

Optimization means a non-linear exploratory process by which a structure is adjusted to achieve a configuration that best meets multiple competing performance requirements or physical attribute requirements. Optimization can be achieved in a single step or many, depending on how demanding the requirements are and how effective the optimization technique is. Optimization may require regression to a prior configuration if one path is determined to be less optimal than another.

Finite Element Analysis (FEA) means the simulation of the behavior of a part or assembly under given physical conditions to allow assessment using the finite element method.

Finite Element Method (FEM) is a generalized numerical method for solving differential equations accomplished by subdividing a complex system into smaller, simpler parts called “finite elements.”

Lattice means a repeated pattern of cell shapes that replace a solid internal volume.

Triply periodic minimal surface (TPMS) means a minimal surface that is the same over a rank 3 lattice of translations, e.g., a gyroid. TPMS structures have no self-intersecting surfaces and create two separate sub-volumes.

Artificial intelligence (AI) means the use of computers to emulate human cognitive functions. AI therefore refers to the use of machines to accomplish tasks via algorithms in a manner similar to human intelligence.

Machine learning (ML) means a subset of AI wherein machines execute algorithms allowing the machines to receive a set of data, learn from the data, and change algorithms based on the information learned.

AI, and ML each refer to multiple techniques rather than a single method of computing.

Supervised learning means the use of labeled training data to perform a machine learning task such as data mining.

Unsupervised learning means the use of unlabeled training data to perform a machine learning task.

### DETAILED DESCRIPTION

The invention as described herein includes systems and methods for implementing artificial intelligence assisted engineering and design of tools, parts, assemblies, and components.

Embodiments of the disclosed invention are hereafter described in detail with reference to the accompanying Figures. Although the invention has been described and illustrated with a certain degree of particularity, it is understood that the present disclosure has been made only by way of example and that numerous changes in the combination and arrangement of parts can be resorted to by those skilled in the art without departing from the spirit and scope of the invention.

The following description with reference to the accompanying drawings is provided to assist in a comprehensive understanding of exemplary embodiments of the disclosed invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

The terms and words used in the following description and claims are not limited to the bibliographical meanings, but are merely used by the inventor to enable a clear and consistent understanding of the invention. Accordingly, it should be apparent to those skilled in the art that the following description of exemplary embodiments of the disclosed invention are provided for illustration purpose only and not for the purpose of limiting the invention as defined by the appended claims and their equivalents.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. Thus, for example, reference to “a component surface” includes reference to one or more of such surfaces.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, the terms “comprises,” “comprising,” “includes,” “including,” “has,” “having,” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be also understood that when an element is referred to as being “on,” “attached” to, “connected” to, “coupled” with, “contacting,” “mounted,” etc., another element, it can be directly on, attached to, connected to, coupled with, or contacting the other element or intervening elements may also be present. In contrast, when an element is referred to as being, for example, “directly on,” “directly attached” to, “directly connected” to, “directly coupled” with, or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under,” “below,” “lower,” “over,” “upper,” and the like may be used herein for ease of description to describe one element or feature's relationship to another element(s) or feature(s) as illustrated in the figures. It will be understood that the spatially relative terms are intended to encompass different orientations of a device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly,” “downwardly,” “vertical,” “horizontal,” and the like are used herein for the purpose of explanation only unless specifically indicated otherwise.

Included in the description are flowcharts and block diagrams depicting examples of the methodology and components which may be used to provide algorithm-aided design of structures. In the following description, it will be understood that each block of such illustrations, and combinations of blocks in such illustrations, can be implemented by computer program instructions. These computer program instructions may be loaded onto a computer or other programmable apparatus to produce a machine such that the instructions that execute on the computer or other programmable apparatus create means for implementing the functions specified in the illustration block or blocks. These computer program instructions may also be stored in a computer-readable memory that can direct a computer or other programmable apparatus to function in a particular manner such that the instructions stored in the computer-readable memory produce an article of manufacture including instruction means that implement the function specified in the illustration block or blocks. The computer program instructions may also be loaded onto a computer or other programmable apparatus to cause a series of operational steps to be performed in the computer or on the other programmable apparatus to produce a computer implemented process such that the instructions that execute on the computer or other programmable apparatus provide steps for implementing the functions specified in the illustration block or blocks.

Accordingly, blocks of the flowchart and block diagram illustrations support combinations of means for performing the specified functions and/or combinations of steps for performing the specified functions. It will also be understood that each block of the illustrations, and combinations of blocks in the illustrations, can be implemented by general or special purpose hardware-based computer systems that perform the specified functions or steps, or combinations of hardware and computer instructions.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. In this context, algorithms and operations involve the manipulation of information elements. Typically, but not necessarily, such elements may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” “words,” or the like. These specific words, however, are merely convenient labels and are to be associated with appropriate information elements.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

### SUMMARY OF THE METHOD

The disclosed invention uses artificial intelligence and/or machine learning methods (AI/ML) to streamline the engineering of 3-D structures. Specifically, an AI model or AI ensemble is trained on a database of engineering design tasks, from which emerge a library of Svoxel shapes that have been evaluated for use in various structures for various purposes and under various conditions. When presented with a new engineering problem, the system uses AI models to select one or more candidate Svoxel shapes based on the design requirements for the structure. Candidate structures need not have been tested previously to be selected by an AI model but could be interpolations between previously tested structures or in some cases, an AI model extrapolates to a new candidate shape based on the library. The system then uses the candidate Svoxel(s) to design the interior of the 3-D structure to have specified properties. In some embodiments, the system uses AI models to generate a new voxel or Svoxel and uses the resulting Svoxel to design the interior of the structure. The engineered structure is then built via a suitable manufacturing means, preferentially through additive manufacturing techniques.

The disclosed method uses groups of voxels, or supervoxels, as the fundamental unit of structural representation and analysis. An individual voxel is used to represent a component part of a larger 3-D structure, much like a pixel is used to represent a component part of a larger 2-D image. A voxel can be any volumetric shape that can be infinitely tessellated in 3-D space, preferentially a cube. Voxel size is a minimum size unit related to the resolution of the manufacturing process. For example, use of additive manufacturing equipment imposes a lower limit on voxel size, which may be the smallest unit that a 3-D printer (additive fabricator) can reliably render, or could be imposed by the size of manufacturing materials. For instance, if a 3-D printer uses titanium particles having a minimum size of 100 micrometers (μm), then voxels must be larger than 100 μm. With the voxel as the smallest possible subunit, the fundamental unit of analysis is an Svoxel, which can range in size from a theoretical minimum of one voxel, up to a theoretical maximum set by the additive fabricator size. For example, if the manufacturing equipment is limited to a 1 meter (m) by 1 m by 1 m volume, the largest Svoxel must be smaller than 1 m³.

A plurality of Svoxels, of the same shape and size or of different shapes or sizes, can be assembled to represent the entire 3-D structure. The fidelity of the representation of a voxelated structure to the actual structure is a matter of resolution, wherein the resolution is determined by available computing power, the properties of the additive manufacturing equipment used to produce the structure, and the manufacturing cost of the structure. The computing power required to approximate the interior of a structure increases as component Svoxels decrease in size, or as the number of different Svoxel shapes or sizes increases. Similarly, manufacturing costs increase if smaller Svoxels are used or when a higher proportion of an Svoxel is filled, because more material is required to fill the volume of the structure. On the other hand, smaller Svoxels will more closely represent the original 3-D structure shape. Typically, an Svoxel will be a group of voxels with a size that is optimized for additive fabricator resolution and size, computing power, manufacturing cost, and structural requirements to achieve fidelity to the 3-D structure. Human input may be required to weight the competing optimization factors since prioritization could depend on specific situational requirements.

The system then creates a final product design by filling the 3-D model with a voxelated render using the selected Svoxel, and an optimized Svoxel size. Similar to the selection of Svoxel shape, optimizing the Svoxel size may require human input to weight different factors like manufacturing cost, weight, ease of manufacturing, or structural performance, each of which could have a different level of importance depending on the project. The resulting structure has the external surface features of the 3-D model as a “skin” over a voxelated interior.

In some embodiments, the system feeds the design constraints into an ensemble of one or more AI models to generate a voxelated render derived from an existing library. The AI ensemble accesses a library of tested Svoxels that have been developed and evaluated for use in previously designed structures. Each AI model may be trained to solve for a design constraint, such as a performance requirement, e.g., tensile strength, crush resistance, deformability, heat dissipation, sound absorption, energy absorption, etc. For example, the AI ensemble may access a database populated by design solutions that optimize a structure's tensile strength, while a second database is populated by design solutions that optimize a structure's heat absorption and another database the structure's crush resistance characteristics. Multiple libraries and databases are possible and contemplated. The tested Svoxels can be of various sizes, shapes, internal geometries, and materials. In some cases, the tested Svoxels have been physically built using additive manufacturing methods and subject to testing for various design parameters. The AI ensemble uses the input constraints and parameters to select one or more candidate Svoxels from the library, fill the Svoxels with internal geometry, and arrange them in a form approximating the structure. The system presents the candidate designs to a user along with relevant characteristics of each candidate design, such as cost of manufacture, time to fabricate, and performance parameters. Human input may be required at this stage to properly weigh the different characteristics. The user then selects a design to be manufactured based on the weighted characteristics of each candidate design.

The system may also use validated Svoxels in the library to design a novel 3-D structure. A user provides certain design constraints of the structure, which may include physical attributes such as size, general shape, volume, weight, cost, etc., or performance characteristics, e.g., strength, energy dampening, heat absorption, heat dissipation, or other property. From the given constraints, the system will use AI models to permutate the design parameters of known Svoxels and arrangements of Svoxels into novel combinations that have not been generated or tested prior. Because the AI models have been trained on performance aspects of shapes in the Svoxel library, the new designs generated will meet the provided design constraints without requiring verification or testing of the new structures.

The trained AI models use learnings from previous builds to predict the characteristics a new structure will require to successfully meet design constraints. When given a new design task, the AI models concurrently weigh the dozens of parameters used to generate a structure, and identify multiple solutions that meet design constraints, each solution having its advantages and disadvantages. Solving such multivariate design problems with AI models provides an unexpected advantage, namely, having relatively more degrees of freedom, i.e., more adjustable variables like Svoxel shape, size, internal geometry, etc., gives system algorithms a higher probability of generating many candidate geometries that meet design constraints.

### Exemplary Process

An exemplary process of generating a solution for a novel structure build follows. Given design constraints from a user, the system starts with a 3-D model of the new structure, which may include curved surfaces, angles, irregular shapes, or other surface features. In specialized cases, the structure is a regular shape, such as a cube, a cylinder, a rectangular prism, or pyramid.

Next, the system performs a recursive process to generate a voxelated render of the 3-D model. The 3-D model is represented by filling the interior volume with Svoxels having one or more shapes, and one or more sizes. Typically, the method will use Svoxels having a cube shape and having the same size, however the method is not so limited. The initial size of the Svoxel can be selected by a number of different means, for example, a system user may select the initial size, initial size may be set by an AI model based on prior builds, a maximum number of Svoxels may be set by the user and the structure subdivided accordingly, the system may select a standard Svoxel size based on the volume of the structure, or other suitable method.

The system will then perform an initial modeling of the structure with the initial size Svoxel, and the solution will be evaluated. The system may perform several such modellings, each starting with a different Svoxel shape, internal geometry, etc. The Svoxel size may then be adjusted, and the solution evaluated again until an Svoxel size is reached that optimizes computing time, performance requirements, cost, shape fidelity, and other suitable criteria. Once the optimal sizes and shapes of Svoxel are selected, the final voxelated render is generated. However, the render will usually not be an exact representation of the 3-D model surface. For example, curved surfaces cannot be smoothly represented, and corners sized smaller than the Svoxel dimensions will not be faithfully duplicated.

Accordingly, after generating the voxelated render, the system optionally reconciles and accounts for the differences between the render and the 3-D model shape by generating a simulation model. Generating a simulation model can provide highly accurate estimates for the forces acting on the render but does so at the cost of increased development time and processing resources. In some cases, a simulation model is not required because the structure is a regular shape, e.g., a cylinder or a square, or is fairly simple. In such cases, the render represents or closely approximates the structure. In other cases, despite there being significant differences between the render and the 3-D model, the time and computing resources required to generate a simulation model outweigh the potential gains in accuracy the simulation model would provide. In such situations, the render may be designed with a safety factor to ensure the final structure is able to meet requirements. By contrast, in applications requiring high levels of accuracy, such as aerospace structures, the costs of developing a simulation model may be justified.

The simulation model is developed by taking the difference between the 3-D model and the voxelated render. The simulation model thus includes only the 3-D model surfaces not duplicated by the render. The system then calculates the interaction between the simulation model surfaces and the render surfaces. For example, this interaction may be the forces applied by the simulation model surfaces onto the render surfaces.

One means of solving for these interactions is to perform finite element analysis (FEA) on the simulation model using the initial design constraints, which generates a set of output parameters relevant to the differences between the 3-D model and voxelated render. FEA derives the simulation output parameters by creating a mesh of smaller elements that combine to approximate the shape of the structure that is being assessed. Each of the constituent elements is subjected to calculations, and the mesh is refined. After multiple iterations, the mesh refinements combine to produce output parameters for the whole structure.

### Svoxel Selection and Design

Svoxel selection and design represents a core function of the disclosed system, and the corresponding testing and data collection on candidate Svoxels are key elements of the AI model.

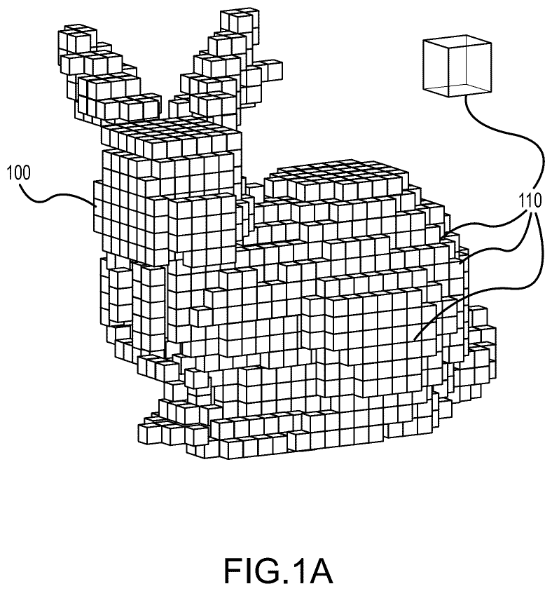

Svoxels are selected or designed to build up a new structure unit-by-unit to meet the given design constraints. With reference to FIG. 1A, a simple and preferred example of an Svoxel shape is a cube. The shape of the structure 100, in this case a rabbit, is represented by a plurality of cubes 110 arranged to fill the internal volume of the structure. As shown, the cubic Svoxels are the same size, but configurations of Svoxels of a plurality of sizes may also be used. Other more complex shapes for voxels are possible and contemplated, such as multi-sided regular polygons (FIG. 1B, 120), which may be arranged into an Svoxel that forms a regular crystal lattice. In other cases, multi-sided irregular polygons (FIG. 1C, 130) may serve as voxels and may be arranged to construct an Svoxel having an aperiodic 3-D structure. In some embodiments, two or more complementary shapes may be arranged together to construct a volume. There is no requirement that Svoxel shapes have regular or consistent faces, as long as the Svoxels can fit together in a tessellated manner, and each Svoxel has predictable behavior within the structure.

Svoxel scale is determined by the needs of the structure, as constrained by the capabilities of the manufacturing equipment, the performance requirements of the structure, and available computational resources. For example, the smallest size a particular additive fabricator can reliably and predictably render a voxel could constitute a lower size limit. Similarly, construction material of a certain particle size may only be suitable for voxels of a certain minimum size. Maximum size limits for Svoxels are set by the size of the structure or the capacity of the additive fabricator. Typically, a wide range of Svoxel sizes will be allowed by the available additive manufacturing equipment and materials.

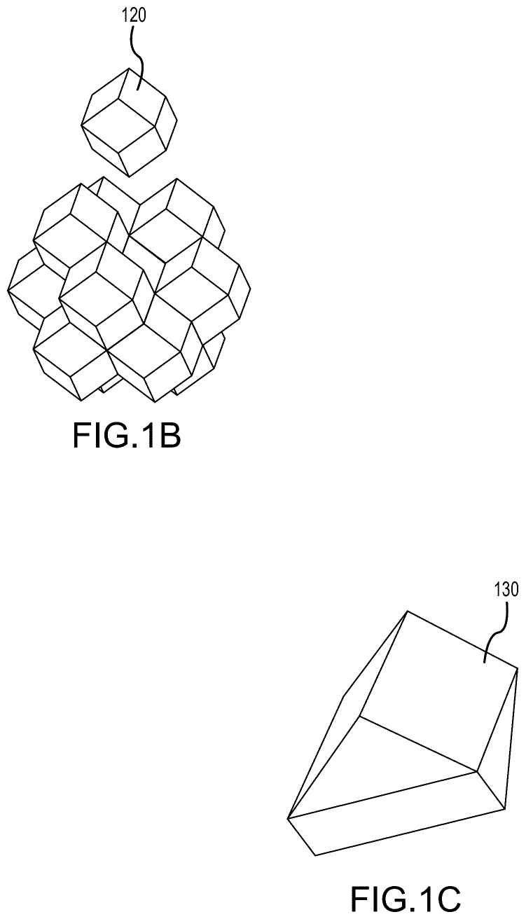

Once a structure has been approximated by an arrangement of individual Svoxels, the Svoxels are filled with geometries. With reference to FIG. 2, several Svoxel internal geometries are depicted. These internal Svoxel configurations include node and beam structures with parameters such as beam thickness, crystal lattice structure, node size, node and beam filleting, beam thickening on a gradient, and periodicity. Such parameters are variable so that the system can adjust performance through use of AI models. Further, AI models are trained on parameter variations and results so that changes to the parameters result in predictable performance outcomes. An exemplary square lattice structure 210 is shown having a relatively high beam thickness 212 and high unit periodicity. By contrast, an example diamond lattice structure 220 is depicted with low beam thickness 222 and relatively low unit periodicity. An example hexagonal cell lattice 230 and complex diamond lattice 240 are also shown. Lattice structures may be modeled on organic or inorganic molecular structures, other naturally occurring structures, or synthetic structures. Structures may be designed having dynamic responses, for example, structures that become stiff when receiving a sharp impact and soft when subject to low intensity pressures (such as found in some combat helmet liners). Multiple lattice structures are possible and contemplated, to include regular 210, 220, 230, 240, and irregular 250 lattice structures.

Svoxel internal geometries are not limited to node and beam structures but may also include continuous surface structures such as a triply periodic minimal surface. Like the node and beam geometries, continuous surface structures have variable parameters an AI model can use to adjust performance, and upon which AI models can be trained to achieve predictable performance outcomes. These parameters include surface thickness, surface thickness adjusted on a gradient, and surface periodicity. Exemplary continuous structures include the Schoen's Gyroid surface 260, the Schwartz-P surface 270, and Schoen's PA Batwing surface 280, among others.

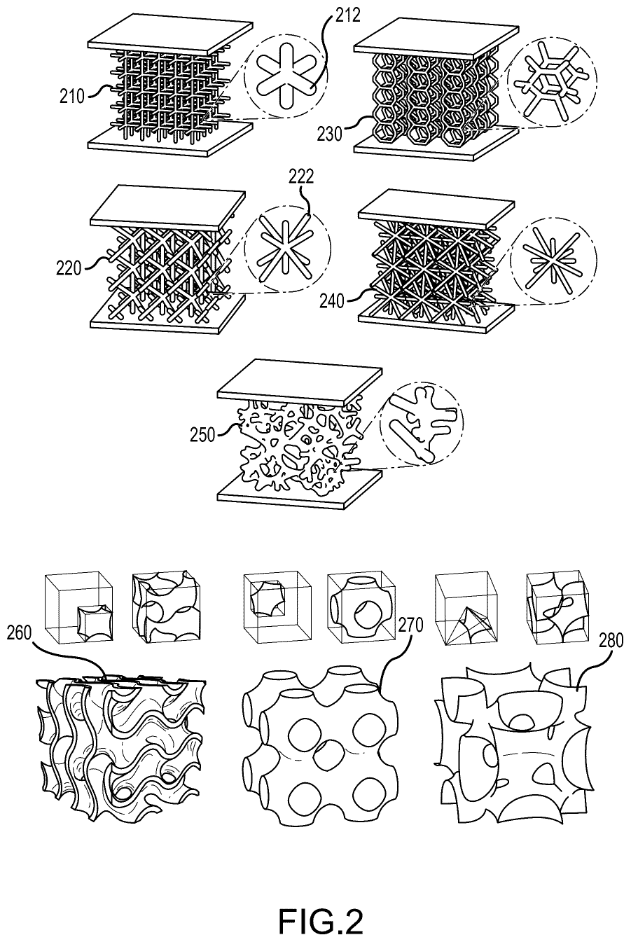

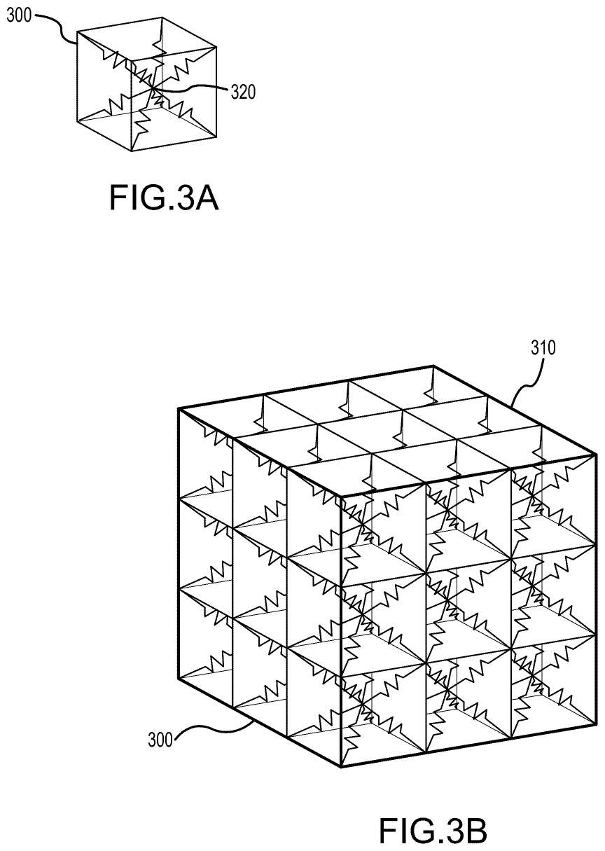

Each lattice or TPMS is represented as a network of Svoxels that have internal performance characteristics. With reference to FIG. 3A is depicted an example voxel 300, which is the basic building block of an Svoxel 310, depicted in FIG. 3B. Here the Svoxel 310 and its nine component voxels 300 are depicted as cubes. The properties of the voxel are modeled as acting upon a central point 320 of the cube, and the internal properties of the Svoxel are modeled as an aggregation of properties of its component voxels. Such internal performance of an Svoxel is the intra-cell performance of the shape. The Svoxels also interact as part of a network of Svoxels, and together form a structure that has performance characteristics as a structure. The overall performance of the Svoxels arranged into a structure is the inter-cell performance of the shape. Given a set of external size and shape constraints for the structure being fabricated, the AI model can vary intra-cell properties of each Svoxel, e.g., size, shape, internal structure, as well as inter-cell properties among the Svoxels, e.g., size, shape, number of voxels, to create a metamaterial that fits within size constraints and satisfies the required performance characteristics of the structure.

New or candidate structures may have their characteristics modeled by performing intra-cell and inter-cell analysis. Through intra-cell analysis, the relationships between specific geometric properties and the effective performance of the Svoxel are identified. Intra-cell characterization of an Svoxel shape yields computational advantages for structural characterization. Once the internal performance of an Svoxel is known, individual Svoxels can be represented as points, and then only the relationships between Svoxels are considered to characterize the inter-cell performance. In this way, intra-cell analysis allows a dimensional simplification similar to finite element analysis (FEA), which reduces processing requirements.

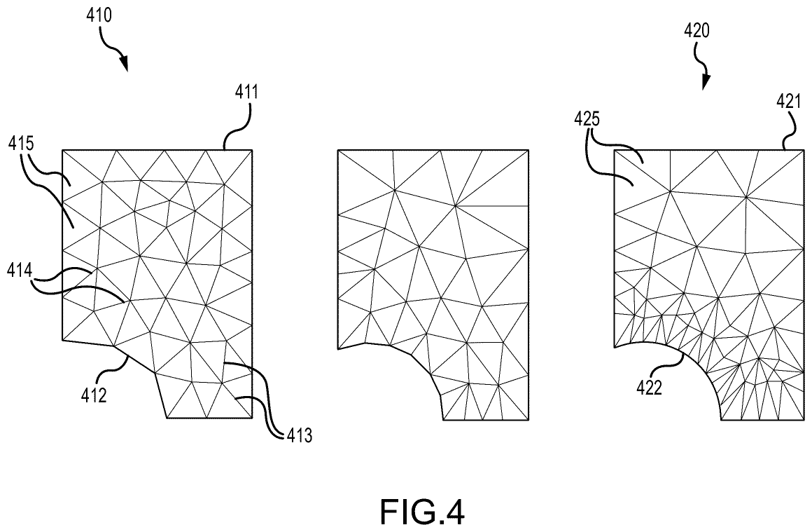

With reference to FIG. 4, an example FEA is depicted. In a first iteration 410, a rectangular 2-D shape 411 with a cut-out section 412 is approximated using 1-D lines 413 that intersect at nodes 414 to form a mesh of triangles 415. The cut-out shape 412 is only roughly approximated due to the larger size of the mesh elements 415. In a third iteration 420, the shape 421 is again approximated by a mesh of triangular cells 425, however after refining the model using smaller cells proximate to the cut out, the cut-out section 422 is more accurately approximated as a partial circle. Therefore, by use of multiple 1-D lines, a complex 2-D shape is represented. Similarly, FEA allows the system to model the performance of a 3-D structure as a sum of points, which reduces computing resources required to generate the solution. The amount of computing resources required for a FEA is determined by the complexity of a mesh, or its resolution. A high-density mesh in proximity to the cut-out shape renders a better approximation of the shape but requires more resources to generate.

With the properties of an individual Svoxel shape sufficiently characterized, inter-cell analysis is performed on different assembly configurations of networks of many Svoxels that make up the lattice or TPMS. The Svoxel configurations are investigated to determine the effects of scaling and arrangement on the performance of the shape. Through inter-cell analysis, the relationships between scaling parameters of multiple Svoxels and the performance characteristics of the shape are identified. In practice, the AI model performs the intra-cell and inter-cell analysis concurrently, since the model extrapolates intra-cell performance to predict the performance of the entire structure based on prior learnings.

In addition to uniform variation of parameters, some parameters such as beam thickness, can be varied according to functional gradients. For example, a part can be designed with a functional gradient so that at the part's first end, beam thickness starts at 1 mm and gradually increases across the part's length until reaching a beam thickness of 10 mm at the part's second end. Performance of the part would thus change across its length according to the functional gradient.

Physical relationships relevant to the particular application are modeled through use of equations and inform geometric design choices such as structural evolution. For example, given a structure that is required to meet a certain performance requirement for thermofluidic management, such as a vehicle exhaust system, the Inverse Square Law requires that temperature and sound reduce inversely proportional to the distance squared. Similarly, the Cube Law states that energy decreases inversely proportional to the velocity cubed, and Boyle's Law states that pressure reduces proportionally to the volume, or as simplified, to a distance from a point of origin. These aspects of thermofluidic management performance are therefore mitigated according to the reduction factor applicable to each aspect. By evolving the design geometries based on different coordinate systems, i.e., linear, cylindrical, spherical, or n-dimensional, the performance of the structure is optimized.

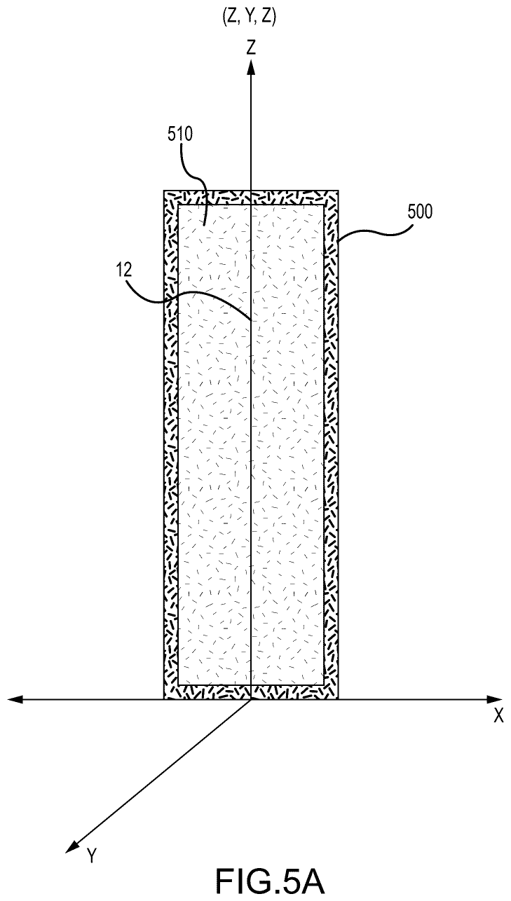

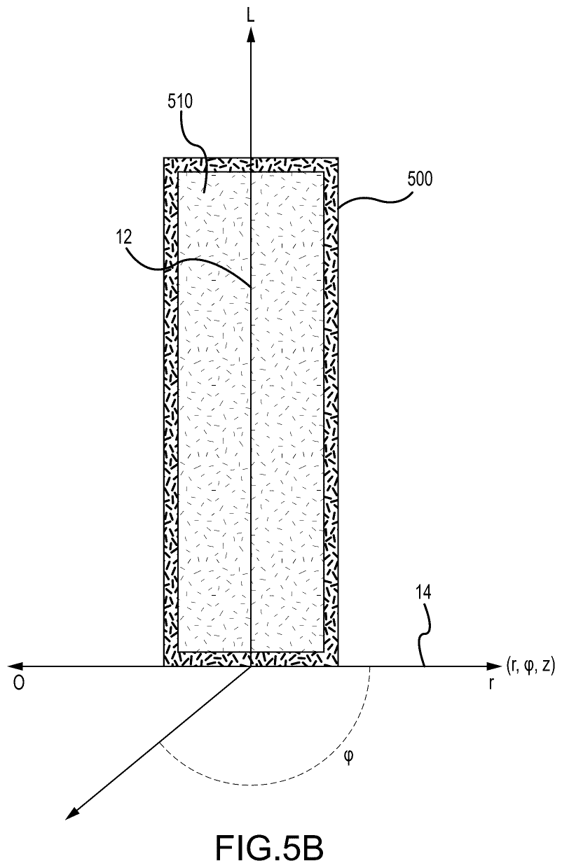

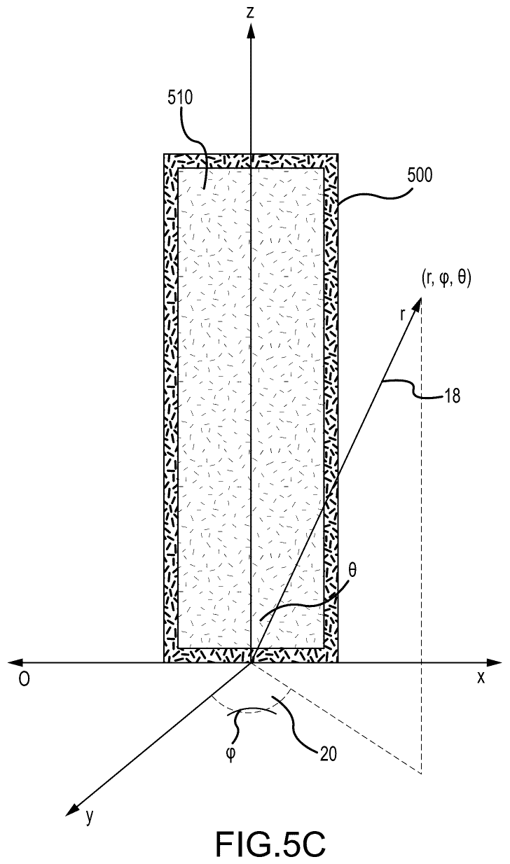

Geometry evolution may be varied by adjusting the periodicity of the performance function. With reference to FIG. 5A, an example geometry evolution along a single axis of a structure 500 is depicted. In this case, the structure's 510 geometry evolves along its length (the z-axis) in the direction of the arrow 12. Accordingly, the performance function is written in cartesian coordinates and has single axis (z-axis) periodicity. Within the structure, components evolve along the length of the structure.

With reference to FIG. 5B, an example geometry evolution on two axes is depicted. Here, the structure's 510 geometry evolves both along its length in the direction of the arrow 12 (the L-axis), but also evolves along the radius 14 extending from the longitudinal axis L of the structure. The performance function is written in cylindrical coordinates and has periodicity that varies over a radial (r) and the longitudinal axis (L-axis). For the structure, components would continuously evolve along its length and also evolve along a radial extending out from the longitudinal axis.

With reference to FIG. 5C, an example geometry evolution on three axes is depicted. In this case, the structure's 510 geometry evolves on radials (one 18 is shown) centered on an origin 20. The performance function for this evolution is written in spherical coordinates and has periodicity that varies from the origin (O) over a radial (r) and the polar angle (0). In the structure, component dimensions would accordingly evolve according to distance from the origin 20.

### AI/ML Systems

Artificial intelligence or machine learning models are used to perform various tasks in embodiments of the disclosed invention. Such tasks include the following: 1) the selection of one or more Svoxel shapes for a structure, 2) the construction of a 3-D model of the structure using the selected Svoxel shape, 3) the selection of one or more internal geometries to fill a selected Svoxel shape, 4) the adjustment of one or more parameters specifying an internal geometry of an Svoxel, and 5) the optimization of the structure by adjusting the selected Svoxel shape, 3-D model, and internal geometry parameters. In each case, an AI model may be trained on data sets to develop predictive models to inform the effect of various configuration changes on structural performance. AI models are required to perform multiple tasks concurrently, since conventional computational methods could require months or years to perform similar analysis. In some cases, AI model predictive capabilities as used herein are not possible using traditional computational methods.

Machine learning systems and methods are used in the disclosed invention to improve the selection and/or design of 3-D structures so that structures can be designed and produced more efficiently, with superior performance and lower cost than other manufacturing methods. For example, an AI model uses data acquired from a built structure and its performance relative to a characteristic, e.g., energy absorption, thermal dissipation, etc., as inputs to train an AI model, which then provides as outputs predicted performance of a structure comprised of an Svoxel shape, a 3-D model, and internal Svoxel geometries. Also included are other suitable techniques and processes described herein in combination with machine learning techniques.

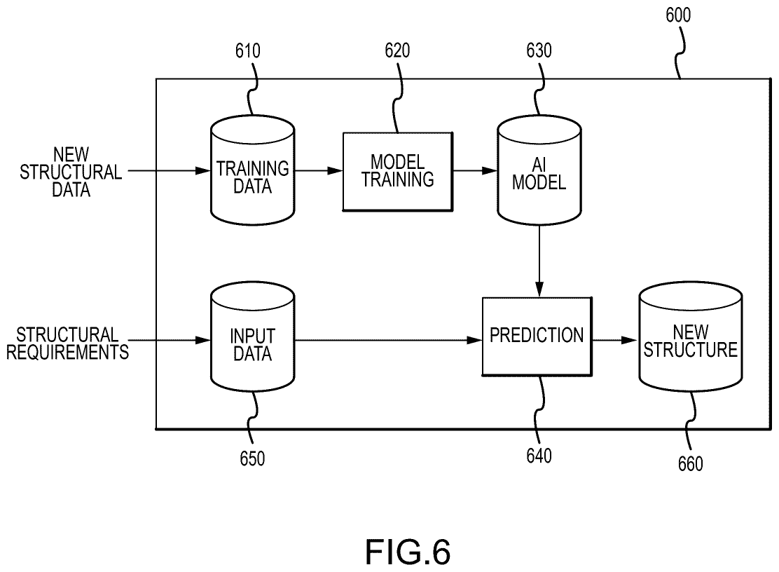

With reference to FIG. 6 is shown a block diagram depicting a generalized machine learning system 600 and a corresponding machine learning workflow as used in embodiments of the disclosed invention. Training data 610 for the system initially includes performance results for structures, or other types of results for structures such as weight, cost, computational complexity, etc., obtained from designed, built, and tested real-world structures constructed using a relevant characteristic, such as Svoxel shape, Svoxel size, Svoxel arrangement, Svoxel internal geometry, etc. In some cases, data derived from computer simulations are used as training data. The system first trains 620 an AI model 630 using a sufficiently large quantity of such data until the model is capable of providing accurate predictions 640 for structural design, performance, or other suitable characteristic. The system bases its prediction upon requirements for a new structure to be built that are provided as input data 650 to the system.

When a design meets requirements, a new structure 660 results. In practice, the system will typically generate several candidate solutions in response to a single inquiry. Such resultant solutions are typically filtered prior to being presented to a system user. For example, some solutions may be impossible or impractical to manufacture, or they may not be compatible with certain manufacturing equipment. Others may be effectively identical to other solutions, e.g., one structure uses internal beam thickness of 1.1 mm, while a second uses a beam thickness of 1.11 mm, so that only one solution is presented. Once the solutions are filtered, the user is presented a set of candidate structures that are manufacturable and reasonable, but which arrive at the structural requirements in different ways and having different advantages and disadvantages. The user then selects a candidate structure for manufacture. Because of this filtering feature, the system is useable by individuals without detailed knowledge of system capabilities and limitations, or manufacturing equipment capabilities.

The system is preferably configured so that it is continuously and/or periodically updated with new training data 610. Some types of ML methods that may be used include the following: supervised, e.g., classification or regression; unsupervised, e.g., clustering and estimation of probability density function; and semi-supervised, e.g., text/image retrieval.

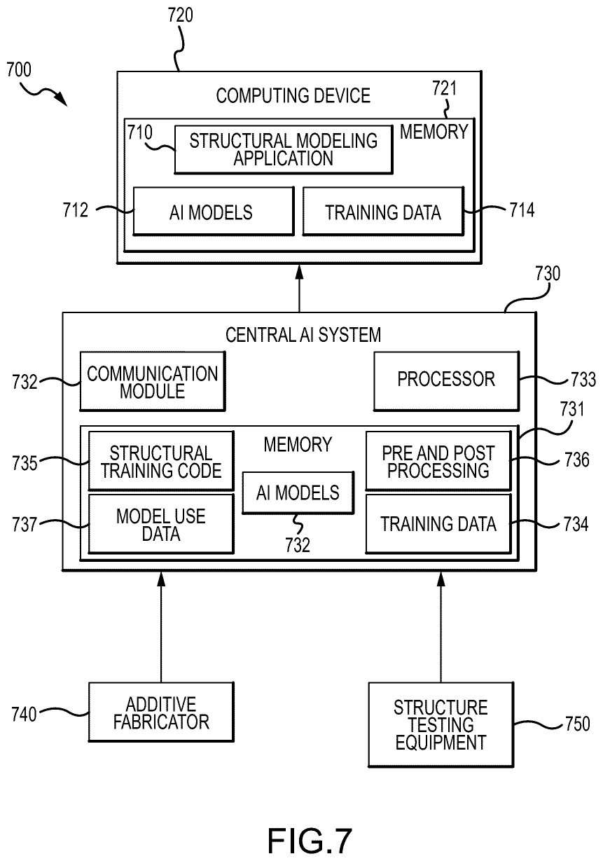

Specific examples of ML systems and methods used to accurately predict the performance of a structure based on inputted structural requirements follow. With reference to FIG. 7 is a block diagram depicting a machine learning system 700 as used in embodiments of the disclosed invention. The system includes two primary components: a structural modeling application (app) 710 that is housed in the memory 721 of a general or specialized computer 720, such as discussed in relation to FIG. 17 below, and a central artificial intelligence system 730. The app 710 is the primary point of access for users and includes the capability to perform certain AI model prediction tasks. The central AI system 730 may be used to perform certain tasks requiring relatively more time or more computing resources, e.g., bootstrapping new structural configurations, than can be performed by the app. In general, the app is used to perform structural design that is backed by extensive AI model construction and training previously performed by the central AI system.

The app 710 accepts inputs from a user specifying characteristics of a structure to be designed for fabrication. Such inputs may include physical attributes, e.g., dimensions, shape, materials, weight, and cost; or performance requirements, e.g., static loading, load distribution, mass minimization, stiffness, damping, center of gravity distribution, impact management, vibration management, heat insulation, heat dissipation, flow control, surface area, aesthetic value, etc. Inputs may also be industry- or application-specific, such as the requirement to use biocompatible materials for medical applications, FAA certification for materials used in aircraft, or other industry-specific requirements. In some embodiments, Svoxel shape, Svoxel number, and internal geometries are specified by a user.

The app may identify one or more AI models or an AI ensemble 712 to predict a physical attribute or performance characteristic for a structural configuration. AI models are selected according to learnings from prior builds, which allow the system to predict which structural configurations are likely to meet the provided design constraints. AI models relevant to those structural configurations are then used to generate a group of candidate structures predicted to meet specified design constraints.

Separate AI models may be required for each characteristic pairing analyzed, e.g., an Svoxel shape for a static loading performance, an Svoxel shape for a heat insulative capability, an Svoxel shape with a type of internal geometry, e.g., a TPMS for acoustic management. AI models may combine structural characteristics and predict a performance or physical attribute. For example, an AI model associates a Svoxel shape, number, and internal geometry with a static loading capability. As another example, an AI model associates an Svoxel shape, number, and internal geometry with a structural cost.

Each AI model may include one or more machine-learning models trained using training data 714 corresponding to a performance characteristic or a structural configuration. For example, training data used to train a given model includes the performance characteristics, e.g., static weight load capability, amount of heat dissipated, that are associated with a given structure, e.g., Svoxel shape, Svoxel number, Svoxel internal geometry, or Svoxel internal geometry evolution. Similarly, training data may include a physical attribute e.g., size, weight, cost, complexity, that is associated with a given structure.

The central AI system 730 has access to more extensive training data 734, including performance and attribute data, and more powerful processors 733 as compared to the app 710. Training data 734 is designated and assembled by the central AI system 730 and communicated to the app training database 714. The app does not have the capability to develop its own training data, since the quality of such data cannot be verified.

The central AI system 730 includes a communication module 732 for performing communication functions with the app, users, training data sources, and other system components as required. A processor 733 performs computer processing functions and may employ multi-core CPUs and/or GPUs to perform computational tasks. Memory 731 stores modules required to perform intensive AI modeling tasks, including a structural training code 735, one or more pre-processing and post-processing functions 736, AI models or AI ensembles 732, AI model use data 737, and training data 734.

The central AI system develops training data for the system, and trains AI models for new structures, e.g., new, i.e., previously uncharacterized, Svoxel shapes, new internal geometries, and combinations of an Svoxel shape with a new internal geometry, etc. The central AI system is preferred for initial training of AI models for performance categories, e.g., static loading, heat dissipation, flow control, acoustic control, etc. The central AI system may also provide initial training databases to the app, and subsequently provide updated training data through use of aggregated learnings from continued empirical characterization from additive fabricators 740 and structure test equipment 750, simulated characterizations, and other data collection performed centrally.

Training data can be derived empirically, through computer simulations, or through other suitable means. For example, empirical data could be derived from the products of an additive fabricator 740. When a designed structure is produced by a 3-D printer, it may present observable defects or qualities that are entered in a database to characterize a structural configuration. Similarly, structures may be manufactured and subjected to tests in physical test equipment 750 to empirically measure performance. For example, a 3-D printed structure is placed in a mechanical compression load frame to determine the static loading performance of the structure. Other performance characteristics may be tested through use of appropriate equipment, such as a decibel meter to assess the noise dampening performance of a firearm suppressor. Then the test results are entered in the central training database 734. Computer simulations may also estimate performance of a given structure and serve as input to a training database.

The central AI system also includes the ability request additional training data by identifying areas in which it produces low-confidence answers. The system can then request additional data in those areas to improve overall model performance. Low confidence areas may be identified by various sampling methods, such as Latin hypercube sampling or other suitable sampling method to identify near-random parameter values from among a multidimensional distribution.

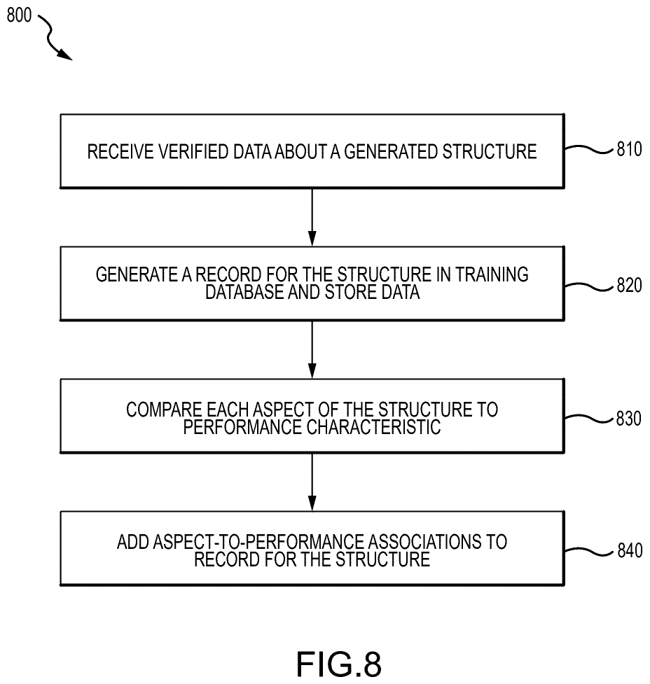

Performance category-level training code 735 controls training and/or definition of one or more performance category-level AI models that generate structural performance and attribute predictions. Each performance category-level AI model may be generated based on training data corresponding to multiple structural configurations and be suitable to generate multiple structure types. In some instances, a performance category-level AI model is trained using a set of data developed through some or all of blocks 810-840 from process 800 depicted in FIG. 8. A performance category-level AI model may include a mathematical model, an ML model, any type of model identified herein or other model. For example, a performance category-level AI model may include a compartmental-based model, a non-compartmental model, a mathematical model, a modified Generative Adversarial Network, a neural network, an ML model that uses a statistical modeling framework, a model using a Monte Carlo simulation, etc.

A performance category-level AI model may be defined for particular types of uses that correspond to characteristics of data used to train the model. For example, a given performance category-level AI model could correspond to a particular type of static loading application, e.g., a bridge, an automobile frame, a pressure vessel, a particular sub-type of the static loading application, e.g., a passenger car, a dump truck, a particular static loading customer, e.g., a passenger car brand, etc. Likewise, performance category-level training code could identify training data to use to train a particular AI model by identifying data for which the constraint(s) of the AI model are satisfied. For example, for a performance category-level AI model that corresponds to the automobile suspension sub-category of system damping, the performance category-level training code identifies structures designed for use as automobile suspension components.

### AI Model Training

An AI model may be trained using training data comprising performance characteristics of newly designed and fabricated structures. Training data can be based on (i) empirically measured performance characteristics of structures, (ii) empirically observed characteristics of fabricated structures, and/or (iii) simulated performance characteristics of structures. Having been trained on such data, the AI model is trained to predict the performance characteristics of a new structure sharing similarities to structures represented in the training data. For example, the AI model can be one that has been trained to indicate a predicted performance characteristic, e.g., stiffness or impact resistance, or to indicate a physical attribute, e.g., weight or cost.

With reference to FIG. 8 is depicted a block diagram showing an exemplary training process 800 for an AI model. The AI model is trained using data related to structures comprised of a particular Svoxel shape and designed to have a certain performance characteristic, such as a structure having a specified weight and specified strength. The AI model first receives data 810 about a created 3-D structure from a source such as a 3-D printer, a testing apparatus, or a simulation. The source would provide manufacturing data, e.g., cost of materials from them manufacturing equipment, while the testing equipment might supply information about static loading strength. The data also includes the various construction parameters of the structure, such as Svoxel shape, Svoxel size, internal geometry, etc. Such data would be curated and verified to ensure quality for training purposes. Next a record 820 for the structure is created in the training database and populated with the received data. Then each aspect or characteristic of the structure, e.g., size, internal cell structure, internal beam width, etc. is associated 830 with one or more performance metrics, e.g., static loading strength, weight, vibration damping, etc. With the aspect-to-performance associations accomplished, these associations are added 840 to the record for the structure stored in the training library.

Having been trained on such data, the AI model is trained to predict the performance of a new structure, e.g., lightweight with specified strength, based on the attributes of that structure. Another model may be trained for the same purpose using data related to structures comprised of a particular Svoxel shape paired with an internal geometry, e.g., a cube filled with a square lattice. The model would therefore be trained to predict the strength of new lightweight structures comprised of cube Svoxels filled with square lattice. Similarly, another model may be trained for the same purpose using data related to structures comprised of the Svoxel shape of various sizes. The model would therefore be trained to predict the strength of new lightweight structures comprised of cube Svoxels that are of a uniform size or of multiple sizes.

As a further example, another model is trained for the same purpose using data related to structures comprised of a particular Svoxel shape paired with an internal geometry wherein the internal geometry evolves according to a certain function, e.g., according to the square of the length of the structure. Such a model would be trained to predict the effect on performance of the structure caused by the evolution of the internal geometry.

Various types of machine learning models can be used. For example, an AI model can be a decision tree, a neural network, or a gradient boosted regression tree. In addition, an AI model may be used to cross check another model to identify structures that are generated by both models. For example, an AI model for thermofluidic performance could find 10 candidate structures, and an AI model for mechanical strength might find 10 candidate structures. Upon cross-checking, the system identifies 3 structures that were generated by both models, meaning those 3 structures will meet both the thermofluidic and mechanical performance requirements for the structure.

### Statistical Modeling Techniques

Characterizing the performance characteristics of new structures requires substantial computational resources, especially where multiple performance dimensions, e.g., Svoxel shape, Svoxel number, internal geometry, etc., are adjusted simultaneously. A rough estimate of the brute force calculations required to characterize multi-dimensional systems is given by the equation c=x^{y}, where c is the computational load, x is a unit of effort, and y is the number of dimensions analyzed. This method also provides a rough estimate of the amount of data required to train an AI model for a functional analysis. Because of these substantial computational and data requirements, standard AI brute force methods are inadequate for multi-dimensional problems such as those required to adequately characterize new or candidate structures.

Therefore, the process uses surrogate modeling techniques to reduce computational loads. Once a quantity of interest is calculated, an adjoint solver using surrogate modeling techniques only needs to solve the derived function, instead of having to calculate a series of individual solutions. Calculating an associated gradient function speeds up data interpolation between calculated points so that computational load scales linearly (rather than geometrically) with the number of additional design parameters.

Adjoint solvers performing surrogate modeling are able to use computational power to evaluate a representation of the geometry and provide an optimized shape for the parameter being investigated. Multiple modeling techniques may be used concurrently, with the best results used as a starting point. For instance, a structural modeling application of the disclosed invention is tasked with designing a ballistic plate for tactical body armor. The ballistic plate design inputs include attributes such as an area, thickness, and weight, and include performance characteristics, such as the ability to stop a .45 caliber high grain ammunition round expressed as impact response to a point load of a given momentum.

Rather than run simulations to assess the performance of multiple design variables and combinations thereof, e.g., Svoxel shapes, sizes, configurations, internal geometries and internal geometry evolution functions, the app employs a surrogate modeling process to select one or more candidate geometries. The universe of potential geometries is visualized as a n-dimensional space, where n is the number of design variables. Given the input attributes and performance requirements, the model selects an area corresponding to a design variable combination likely to satisfy the inputs. From the initial ballpark selection of candidate geometries, the AI model refines the various design variables to produce an optimized design.

In some embodiments, multiple adjoint solvers are used in an optimization loop, wherein the output of a first adjoint solver is fed to a second adjoint solver, and so on. For example, the first adjoint solver selects among various Svoxel shapes, the second adjoint solver selects among multiple possible internal geometries, while a third adjoint solver allows selects from among multiple internal geometry evolutions. Multiple solvers may be used, each configured to address a different design parameter, and solutions are chosen according to consensus or majority solution among the solvers.

Having more degrees of freedom improves the probability of identifying viable solutions. For example, solving for 2 parameters might generate 100 candidate shapes, where solving for 10 parameters might generate 3 candidate shapes. The optimization loop may be configured to run a set number of cycles, or to stop running loops once changes converge to a solution. By using optimization loop techniques, the designed structure can evolve to suit the required parameters, e.g., the impact response of a ballistic plate of given size and weight.

### Example Structure Creation

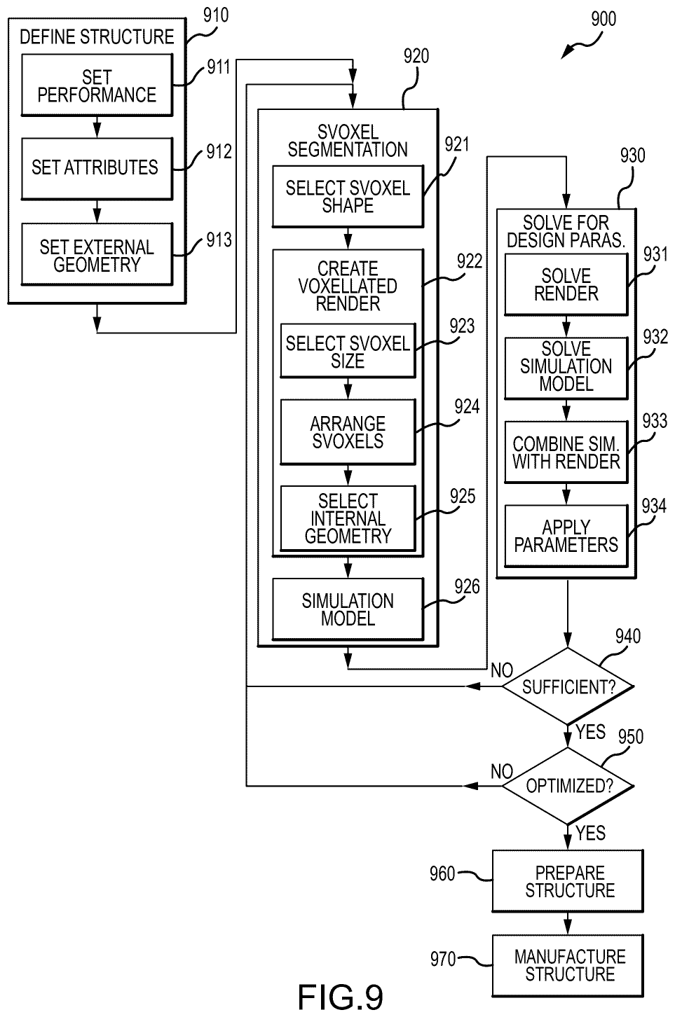

An example process of developing a novel structure according to the disclosed method will now be related. With reference to FIG. 9, a flow chart 900 showing the process is depicted. First the structure is defined 910 by setting the performance parameters 911, e.g., static loading resistance, impact resistance, etc., and by further setting attributes 912 for the structure, e.g., weight, cost, materials, etc. Then the structure's outer geometry 913 is established. The outer geometry as a design input informs the AI model of the characteristics that can be modified, and those that cannot. For example, the part could have a dimension that cannot be modified, or it might have a screw hole that cannot be changed or moved.

Next, the part is segmented into Svoxels 920, each of which can be optimized, and the overall configuration of Svoxels optimized to meet design parameters. Svoxel segmentation has several ramifications, i.e., it greatly simplifies the design, reducing the required computational power; it causes a loss of detail, especially if the Svoxels are large relative to the size of the part; and design performance is reduced because of the imperfect fidelity to the original external geometry. These shortcomings may be mitigated by use of an optional simulation model.

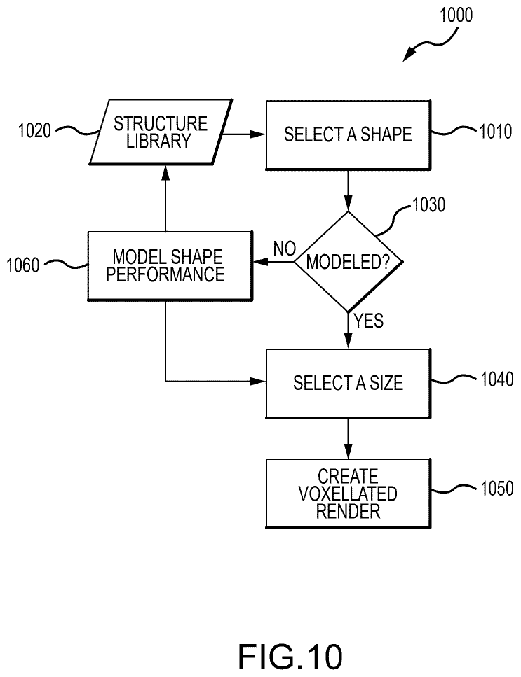

First, an Svoxel shape is selected 921. The shape could be a cube, regular polygon, irregular polygon, TPMS topology, or other suitable shape as discussed above. With reference to FIG. 10, a flow chart depicting at least a portion of the shape selection process 1000 is shown. In some cases, a candidate shape 1010 is retrieved from a library 1020 of structures that have been evaluated for use in a structure suitable for the set performance characteristic, or modeled by an AI model. In other cases, the shape 1010 may be newly selected having not been previously modeled. Therefore, the process makes a selection 1030 based on whether the selected shape has undergone modeling. If the shape has been modeled, the process continues to select an Svoxel size 1040 and then creates a voxelated render 1050. If the shape has not previously been modeled, it will undergo AI modeling 1060, the modeled shape will be added to the structure library 1020, and then the process continues to the size selection step 1040.

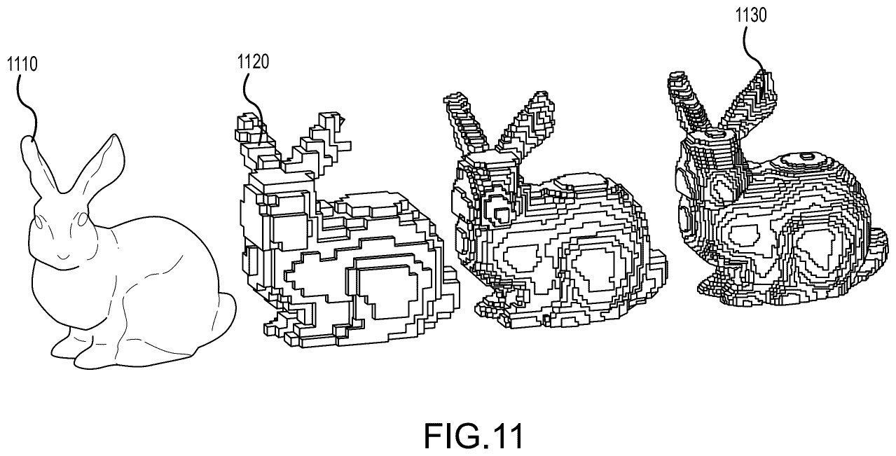

With further reference to FIG. 9, with an Svoxel shape selected, the process continues to create a voxelated render 922 that is predicted to meet design constraints by selecting an Svoxel size 923, populating the shape 924, and selecting an internal geometry 925. With reference to FIG. 11, a basic method of arranging Svoxels within a geometry 1110 is to take an array of Svoxels of a known size, overlay them in the structure, and delete any Svoxel that intersects with the 3-D surface of the part. As shown, the initial external geometry 1110 is voxelated using Svoxels having a cubic shape with a relatively large size 1120. Use of larger Svoxels allows for lower computational loads, and a simpler render, which reduces the number of predictions the AI ensemble will require to determine the fill structure of the Svoxels. As can be seen, however, use of larger Svoxels means that substantial detail and geometry are lost from the original external geometry 1110. Use of smaller Svoxels results in a more accurate render 1130. Unfortunately, the computational loads required to reduce Svoxel size make it impractical to simply reduce Svoxel size infinitely to improve the fidelity of the render. For example, moving to a smaller cube having ½ the length, width, and height of the original cube increases computational load 8 times, and moving to a smaller cube with ⅓ of the original dimensions increases computational load 27 times.

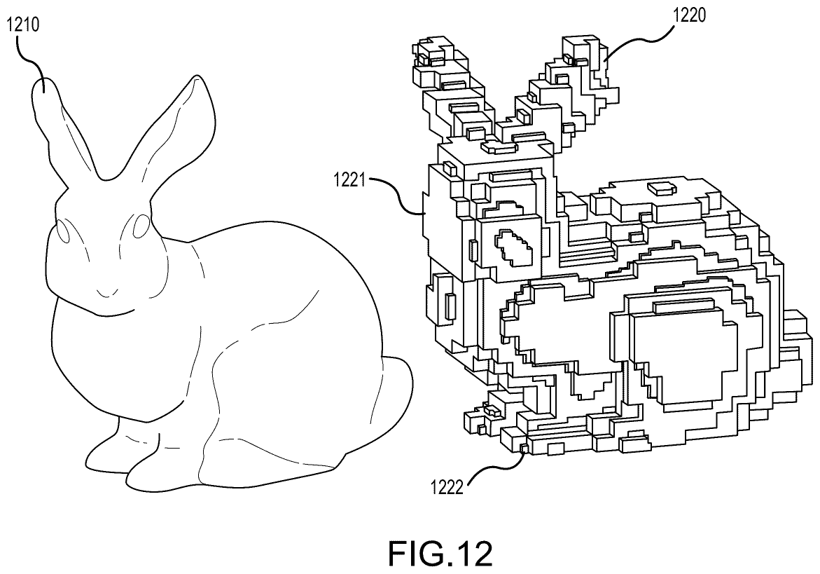

A preferable means of producing a high fidelity voxelated render while minimizing computational load is through use of a hybrid size approach. With reference to FIG. 12, the initial external geometry 1210 is represented by a render 1220 comprising cubic Svoxels of varying sizes. Larger Svoxels 1221 are used to fill large volumes, while smaller Svoxels 1222 are used to fill in more detailed areas. Such a hybrid approach requires algorithms to subdivide the original external geometry into components while balancing computational workload with the degree of deviation of the render to the external geometry. The hybrid voxelated approach reduces overall computational load while providing a more precise render as compared to a uniform size Svoxel representation. However, the hybrid approach requires more sophisticated adaptive algorithms to subdivide the part into volumetric component parts and determine the size of Svoxels to fill each one.

With further reference to FIG. 9, once the Svoxels are arranged 924, the internal geometry 925 of the Svoxels is selected. The internal geometry is selected from among a regular lattice structure, an irregular lattice structure, a lattice with dynamic responses, a continuous structure, or other suitable internal geometry. Internal geometries will be initially characterized with node and beam thicknesses, or surface thicknesses in the case of a continuous surface. In some cases, such characteristics will be adjusted on a gradient across the structure, or according to a periodicity across the structure.

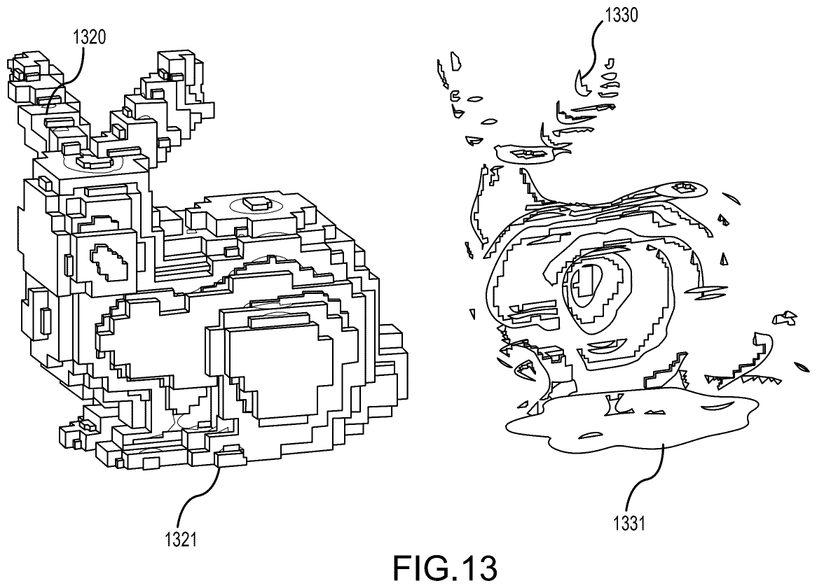

Once a suitably accurate voxelated render is developed and populated with internal geometry, the render is optionally subtracted from the original external geometry to create a simulation model 926. With reference to FIG. 13, the render 1320 is subtracted from the external geometry (see FIG. 11, item 1110) to create the simulation model 1330. The simulation model is comprised of bits of geometry that are too small to be represented by Svoxels, and usually represents less than 0.5% of the total volume. In some cases, the simulation model is not used, but the render is adjusted to provide a safety margin to ensure the design is sufficient.

With further reference to FIG. 9, now that the entire structure is represented, the system accounts for the design parameters required for the part by solving the entire structure for performance and attributes 930. First, the voxelated render is solved 931 by performing intra-cell analysis of each Svoxel and then inter-cell analysis of the Svoxel arrangement.

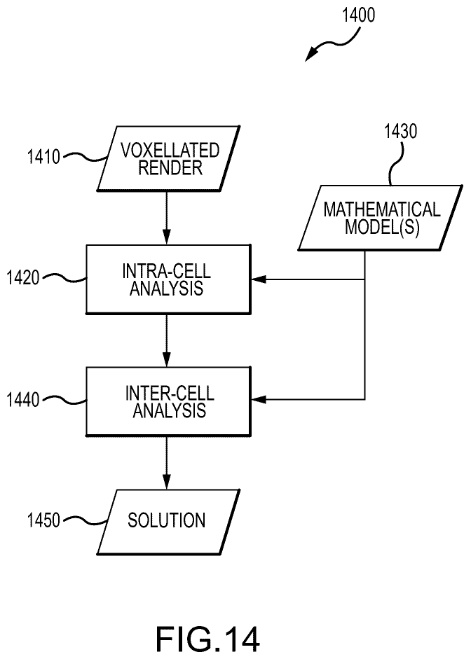

With reference to FIG. 14, an example solve process 1400 for a voxelated render is shown. Given a render 1410 that includes Svoxels having an internal geometry and arranged to fit the external geometry of the designed structure, the system first evaluates the intra-cell behavior 1420 of each Svoxel by characterizing a performance metric for a single Svoxel. Using one or more mathematical models 1430 representing the performance requirements set for the structure, e.g., an equation representing static loading response, an equation representing thermofluidic flow, etc., the relationships between specific geometric properties of the Svoxel and its corresponding performance are identified. After the properties of an individual Svoxel shape and internal geometry are sufficiently characterized, inter-cell analysis 1440 is performed on the Svoxel arrangement using the mathematical model(s) 1430. Through inter-cell analysis, the relationships between scaling parameters of multiple Svoxels and the performance of the entire system are identified. Intra-cell characterization 1420 of an Svoxel shape yields computational advantages for structural characterization. Once the Svoxel's internal performance metric is known, individual Svoxels can be represented as points, and then only the relationships between Svoxels are considered to characterize the inter-cell performance. In this way, intra-cell analysis allows a dimensional simplification similar to FEA.

With the voxelated render solved, if using a simulation model, the system then solves the simulation model 932 by FEA analysis of its geometries in light of the applicable mathematical model(s). FEA allows the system to model the interfaces between the simulation model and the render as a 2-D surface. Other means for solving for the interaction between the simulation model and the render may also be used, for example, force interactions may be manually calculated, smaller volumes may be simulated and the result extrapolated, or solutions may be generated from previous tests of similar structures, etc. The computed solution of the simulation model and the render are then combined 933 to represent the solution to entire approximated structure.

With the entire structure characterized, the structure is subjected to its design constraints 934 to generate performance metrics for the design. With further reference to FIG. 13, if, for example, static loading of the structure is a set performance requirement, the system determines the grounded areas 1321, 1331 of the voxelated render and the simulation model, respectively, and from there determines what forces will be applied to the structure and where they are applied. Then if using a simulation model, FEA is run on the simulation model 1330 using the performance parameters to determine the forces that will be applied to the Svoxels in the render 1320. With the forces from the simulation model and the behavior of the render determined, all input forces on each Svoxel in the render are characterized. The system can then determine the amount of static loading that the structure can support.

With further reference to FIG. 9, the system compares 940 the design's performance metrics to the design parameters to determine whether the design meets performance and/or attribute requirements. If the structure as designed does not meet the set design requirements, the system returns to the Svoxel segmentation step 920, where the structure may be completely or partially redesigned with assistance from AI model(s). If the structure as designed is able to meet the set design requirements, the system determines 950 if the design has been optimized. If the design is not optimized, the system uses an AI model or AI ensemble to recursively adjust the voxelated render 922 by adjusting Svoxel size, the composite arrangement of Svoxels, internal geometry, and internal geometry variations to optimize design performance and attributes. Once the structure is optimized, the design is prepared for manufacturing 960 and then can be manufactured 970.

In cases where the system has access to a library of Svoxel shapes with known characteristics, surrogate modeling techniques may be used to select a starting point for the Svoxel segmentation step 920. Instead of selecting an Svoxel shape, size, and internal geometry at random, the system takes the defined structure 910 and uses surrogate modeling techniques to select a candidate geometry predicted to meet the defined requirements. Surrogate modeling can therefore greatly improve system efficiency and reduce the time required to arrive at a suitable design. Library access may also be used to improve the efficiency of the optimization process. Using an AI model trained on the library, the system can anticipate which structural adjustments will most likely improve the structure in relation to the required performance. For example, the AI model could predict that to optimize performance of a particular design, the Svoxel number should be increased, the internal geometry should be changed from a square to a diamond-shaped lattice, and the beam thickness should increase on a steeper gradient.

### Purpose-Based Design

The process for designing a new Svoxel shape is fundamentally based on the purpose of the structure and the physical attributes required to fulfill that purpose. Different purposes are possible and contemplated. For example, a structure could be required to perform within different mechanical situations, such as withstanding static loads, withstanding dynamic loads, mitigating vibration, mitigating physical impacts, withstanding cyclical loading, absorbing energy, dissipating energy, or some combination of these qualities. Additionally, a structure could be designed to perform in other physical domains, e.g., thermal loading, acoustic processing, fluid flow control, so long as the basic mathematics behind such interactions is understood.

With further reference to FIG. 9, the system accounts for the purpose of the structure when a user defines the structure 910, when the system sets an initial Svoxel segmentation 920, and when the system solves for structural performance 930. At the define stage, the system receives from a user the performance requirements of the structure, which establishes whether the structure will be designed to mitigate vibration, control thermal transmission, manage acoustic energy, etc. At the segmentation stage, the system may begin Svoxel shape selection 921 and voxelated render creation 922 from an uninformed position requiring a bootstrapping process that includes trial and error investigation of designs. What is more likely, the system will have training data on structures for a similar purpose with which to train an AI model or AI ensemble. In such cases, the system uses an AI model to predict a starting shape and configuration that is likely to lead to a suitable design. Alternatively, with sufficient training data, the system uses a surrogate modeling technique to select one or more starting designs suitable for the purpose.

However, the primary location of customization for different purposes takes place in the solve step 930. The solve step includes solving for the voxelated render through intra-cell and inter-cell analysis, and analysis of the simulation model. These analytics require the definition and use of mathematical model(s) that sufficiently characterize the physical relationships required to execute the purpose. It is thus in the solve step that the system determines the suitability of a particular design for a particular purpose, and the results of the solve step are required to train the AI model(s) used in the segmentation step.

In the case of mechanical stiffness, discussed below, an existing standardized test is available for characterizing the necessary performance characteristics of the unit cell geometry. However, such tests are not available for every required performance characteristic. To train the AI models to characterize these other properties, all relevant criteria must be identified, and a proper test developed for each property. Uniform test parameters for each property are developed to limit variations between test runs, and test instrumentation designed to test only the performance characteristic of interest while limiting unintended variation between specimens. An AI training workflow is needed to collect the relevant data, process it, and store it for feeding to the AI model. Once developed, the training workflow is automated to increase the rate of data collection and provide more data for AI model training, which will result in a more robust and accurate characterization of new Svoxels and Svoxel arrangements. The AI model may be trained to solve for different performance parameters, e.g., tensile strength, compressive strength, deformability, heat dissipation, sound absorption, energy absorption, fluid flow control, etc., each of which may require a separate database of solutions, and therefore separate training of AI models.

### Static Loading

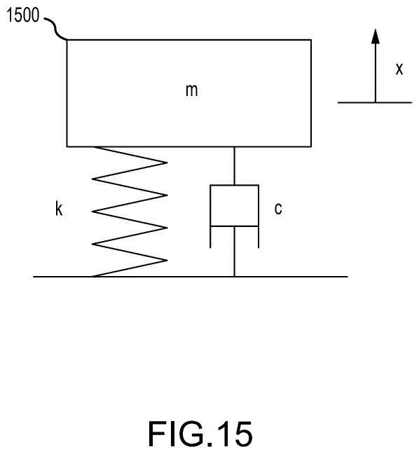

An exemplary process for designing Svoxels for use in structures optimized for static loading conditions will now be discussed. First, the mechanical properties of the generated Svoxels and Svoxel networks are modeled by defining a preliminary intra-unit cell mass-spring-damper model and an inter-unit cell mass-spring-damper model. Each of these models relies on a system-level simplification: the mass-spring-damper representation. With reference to FIG. 15, in a mass-spring-damper system 1600, the performance of the system is modeled as a second-order differential equation:

$$\sum F = {F}_{external} - kx - c \dot{x} = m \ddot{x}$$

Where x represents the displacement of the mass m, k is the stiffness coefficient, and c is the effective damping constant. From this relation, a more general expression can be formed:

$$\ddot{x} + 2 ξ {w}_{n} \dot{x} + {w}_{n}^{2} x = u$$

Where ξ is the damping ratio, wₙ is the natural frequency of the system (equivalent to \sqrt{k/m}), and u is a representation of the system excitation. In order to limit the scope of the first iteration of the Svoxel design process, only the static response of the system will be considered, meaning the total displacement is assumed to be constant, i.e., the first derivative and second derivative of x(t) are zero. With this assumption in place, only the stiffness k of the system is needed to achieve a sufficient model.

The new Svoxel geometries have their mechanical stiffness defined by first performing intra-cell analysis, which identifies the relationships between specific geometric properties and the effective stiffness of the unit cell. After the properties of an individual Svoxel shape are sufficiently characterized, inter-cell analysis is performed on different assembly configurations of networks of many Svoxels. The Svoxel configurations are investigated to determine the effects of scaling and arrangement on the mechanical performance of the system of Svoxels. Through inter-cell analysis, the relationships between scaling parameters of multiple Svoxels and the effective stiffness of the entire system are identified.

In some embodiments, in addition to testing the new Svoxel under the constant displacement assumption, the dynamic response of the system is characterized. Different dynamic responses can be modeled, such as vibrational input or a mechanical shock input. To characterize these different responses, the damping characteristics of the system will need to be defined, and a test designed for testing such characteristics.

In some embodiments, the disclosed method is modified to add a safety factor to a structure by solving for a range of values for each investigated parameter. For example, rather than optimizing a structure to achieve a particular impact resistance, the system would evolve the structure to meet a range of impact forces. The evolved Svoxel structure would thus have an operational window centered on a targeted impact value and a definable percentage around that value. The use of a safety factor would reduce the risk of failure due to “noise” or inaccuracies in the simulations. The safety factor would also compensate for engineering errors, such as a poor estimate of the impact resistance required by a structure or would allow a user to overengineer a part to ensure adequate performance in unexpected situations.

### Computer System

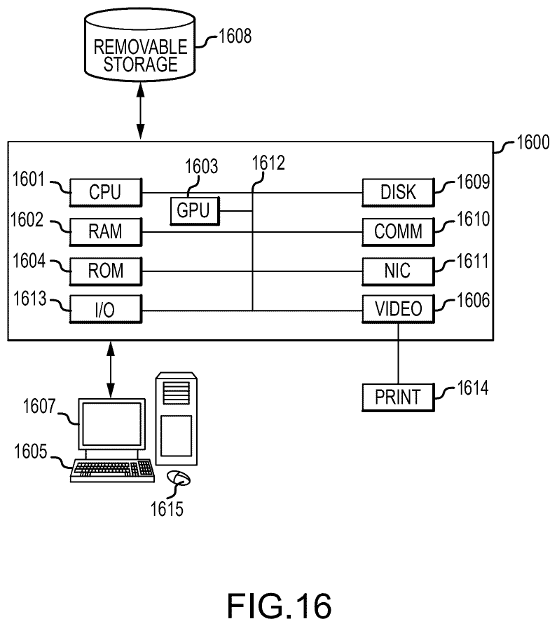

One having skill in the art will recognize that portions of the disclosed invention may be implemented on a specialized computer system, or a general-purpose computer system, such as a personal computer (PC), a server, a laptop computer, a notebook computer, or a handheld or pocket computer. FIG. 16 is a block diagram of a general-purpose computer system in which software-implemented processes of the disclosed invention may be embodied. As shown, the system 1600 comprises one or more central processing unit(s) (CPU) or processor(s) 1601 coupled to a random-access memory (RAM) 1602, a read-only memory (ROM) 1604, a keyboard or user interface 1605, a display or video adapter 1606 connected to a display device 1607 (e.g., screen, touchscreen, or monitor), a removable storage device 1608 (e.g., flash drive, floppy disk, cloud storage, etc.), a fixed storage device 1609 (e.g., hard disk, flash memory), a communication (COMM) port(s) or interface(s) 1610, and a network interface card (NIC) or controller 1611 (e.g., Ethernet, wi-fi, cellular, near-field communication, etc.). Some embodiments include a graphics processing unit(s) (GPU) 1603. Although not shown separately, a real time system clock is included with the system, in a conventional manner.

The CPU 1601 comprises a suitable processor for implementing the disclosed invention. In some embodiments, a GPU 1603 may supplement computational tasks as is known in the art. The CPU 1601 communicates with other components of the system via a bi-directional system bus 1612, and any necessary input/output (I/O) controller 1613 circuitry and other “glue” logic. The bus, which includes address lines for addressing system memory, provides data transfer between and among the various components. RAM 1602 serves as the working memory for the CPU 1601. ROM 1604 contains the basic I/O system code (BIOS), which is a set of low-level routines in ROM that application programs and the operating systems can use to interact with the hardware, including reading characters from the keyboard, outputting characters to printers 1614, etc.

Mass storage devices 1608, 1609 provide persistent storage on fixed and removable media, such as magnetic, optical, or magnetic-optical storage systems, flash memory, cloud servers, or any other available mass storage technology. The mass storage may be shared on a network, or it may be dedicated mass storage. As shown in FIG. 16, fixed storage 1609 stores a body of program and data for directing operation of the computer system, including an operating system, user application programs, driver, and other support files, as well as other data files of all sorts. Typically, fixed storage 1609 serves as the main data storage for the system.

In operation, program logic (including that which implements methodology of the disclosed invention described herein) is loaded from the removable storage 1608 or fixed storage 1609 into the main (RAM) memory 1602, for execution by the CPU 1601. During operation of the program logic, the system 1600 accepts user input from a keyboard and pointing device 1615, as well as speech-based input from a voice recognition system (not shown). The user interface 1605 permits selection of application programs, entry of keyboard-based input or data, and selection and manipulation of individual data objects displayed on the screen, touchscreen, or display device 1607. Likewise, the pointing device 1615, such as a mouse, track pad, track ball, pen device, or a digit in the case of a touchscreen, permits selection and manipulation of objects on the display device. In this manner, these input devices support manual user input for any process running on the system.

The computer system 1600 displays text and/or graphic images and other data on the display device 1607. The video adapter 1606, which is interposed between the display 1607 and the system bus, drives the display device 1607. The video adapter 1606, which includes video memory accessible to the CPU 1601, provides circuitry that converts pixel data stored in the video memory to a raster signal suitable for use by a display monitor. A hard copy of the displayed information, or other information within the system 1600, may be obtained from the printer 1614, or other output device.

The system itself communicates with other devices (e.g., other computers, other networks) via the NIC 1611 connected to a network (e.g., Ethernet network, wi-fi, near field communication network, etc.). The system 1600 may also communicate with local occasionally connected devices (e.g., serial cable-linked devices) via the COMM interface 1610, which may include a serial port, a Universal Serial Bus (USB) interface, or the like. Devices that will be commonly connected locally to the interface 1610 include desktop computers, laptop computers, handheld computers, etc.

The system may be implemented through various wireless networks and their associated communication devices. Such networks may include mainframe computers, or servers, such as a gateway computer or application server which may have access to a database. A gateway computer serves as a point of entry into each network and may be coupled to another network by means of a communications link. The gateway may also be directly or indirectly coupled to one or more devices using a communications link or may be coupled to a storage device such as a data repository or database.

Configurations and architectures of AI models other than those explicitly described and disclosed herein can also be used obtain similarly useful results. Whether located in a remote cloud server, air-gapped server, a laboratory, an additive manufacturing shop, a design studio, or another type of location, machine learning training, updating, computations, and analyses can be are carried out using hardware and computer systems similar those described herein, or using other individual, portable, stationary, conventional, network-based, and/or cloud-based hardware and computer systems. Use of a connected cloud server would allow for constant updates with the best information available, while local deployment provides the most data security, but at the cost of using older data until it can be updated.

It will also be understood by those familiar with the art, that the invention may be embodied in other specific forms without departing from the spirit or essential characteristics thereof. Likewise, the particular naming and division of the modules, managers, functions, systems, engines, layers, features, attributes, methodologies, and other aspects are not mandatory or significant, and the mechanisms that implement the invention or its features may have different names, divisions, and/or formats. Furthermore, as will be apparent to one of ordinary skill in the relevant art, the modules, managers, functions, systems, engines, layers, features, attributes, methodologies, and other aspects of the invention can be implemented as software, hardware, firmware, or any combination of the three. Wherever a component of the disclosed invention is implemented as software, the component can be implemented as a script, as a standalone program, as part of a larger program, as a plurality of separate scripts and/or programs, as a statically or dynamically linked library, as a kernel loadable module, as a device driver, and/or in every and any other way known now or in the future to those of skill in the art of computer programming. Additionally, the disclosed invention is in no way limited to implementation in any specific programming language, or for any specific operating system or environment. Accordingly, the disclosure of the disclosed invention is intended to be illustrative, but not limiting, of the scope of the invention.

What is claimed is:

1. A system for designing three-dimensional (3-D) structures, comprising:
a central artificial intelligence (AI) system comprising: a processor; a communications module; memory for housing a system training database and one or more system AI models; and
a software application run on a computing device, comprising: an application training database and one or more application AI models;
wherein the central AI system receives structural data about a 3-D structure, and wherein the central AI system populates the training database with training data using the structural data and trains the one or more system AI models using the training data; and
wherein the central AI system provides to the software application one of the following: training data to populate the application training database and the one or more application AI models.

2. The system for designing 3-D structures of claim 1, the central AI system further comprising: a structural training code module; an AI model use module, and a pre- and post-processing module.

3. The system for designing 3-D structures of claim 1, wherein the central AI system periodically updates the application training database and the one or more application AI models.

4. The system for designing 3-D structures of claim 1, wherein the application uses the application training database to train the one or more application AI models.

5. The system for designing 3-D structures of claim 1, wherein the application is configured to receive from a user one or more design constraints for the structure, wherein the one or more design constraints includes a performance requirement, or a physical attribute.

6. The system for designing 3-D structures of claim 1, wherein the training data includes a library of shapes that have been used in a prior structure and associated with a performance characteristic.

7. The system for designing 3-D structures of claim 1, wherein each of the one or more system AI models is trained to solve for a performance requirement.

8. The system for designing 3-D structures of claim 1, wherein the application uses the one or more application AI models to generate one or more structures meeting a performance requirement or a physical attribute.

9. The system for designing 3-D structures of claim 1, wherein the application presents to the user a plurality of candidate structures, each of which meets a performance requirement or an attribute requirement.

10. The system for designing 3-D structures of claim 1, wherein the application determines that there is no candidate structure that meets a performance requirement or an attribute requirement.

11. A computer-implemented method for designing three-dimensional (3-D) structures,
comprising:
receiving an external geometry for a structure;
receiving a set of design parameters for the structure including a performance requirement and an attribute requirement;
selecting a shape of a volumetric unit;
creating a render of the structure using the shape, the set of design parameters, and an AI model, comprising: selecting a size of the unit; arranging the units to approximate the external geometry; and selecting an internal geometry of the unit;
solving for a performance metric of the render;
comparing the performance metric to the set of design parameters to determine if the render meets the set of design parameters; and
determining if the render is optimized;
generating, using the render, a solution for the structure.

12. The computer-implemented method for designing 3-D structures of claim 11, the comparing step further comprising:
returning to the selecting step if the render does not meet the set of design parameters.

13. The computer-implemented method for designing 3-D structures of claim 11, the determining step further comprising:
returning to the creating step if the render is not optimized; and
adjusting the render in a recursive manner until the render is optimized.

14. The computer-implemented method for designing 3-D structures of claim 11, further comprising:
subtracting, after the using step, the render from the external geometry to create a simulation model;
solving for a model performance metric of the simulation model;
combining the model performance metric and the performance metric to calculate a combined performance metric;
comparing the combined performance metric to the set of design parameters to determine if the render and simulation model meet the set of design parameters;
determining if the render and simulation model are optimized; and
generating, using the render and the simulation model, a solution for the structure.

15. The computer-implemented method for designing 3-D structures of claim 11, the selecting step further comprising:
retrieving a candidate shape from a library of tested shapes, wherein each tested shape has been evaluated for use in a structure having a performance characteristic.

16. The computer-implemented method for designing 3-D structures of claim 11, the solving step further comprising:
performing an intra-cell analysis on a representative sub-unit of the render; and
performing an inter-cell analysis on the render using the intra-cell analysis.

17. The computer-implemented method for designing 3-D structures of claim 11, the selecting step further comprising selecting a candidate shape and an internal geometry using surrogate modeling techniques.

18. The computer-implemented method for designing 3-D structures of claim 11, the selecting step further comprising: using a plurality of solvers to select a candidate geometry, wherein the candidate geometry includes a unit shape, a unit size, an internal geometry, and an internal geometry evolution.

19. The computer-implemented method for designing 3-D structures of claim 11, the selecting step further comprising:
using a first solver to select one or more candidate shapes to satisfy a first performance requirement;
using a second solver to select one or more candidate shapes to satisfy a second performance requirement; and
selecting a candidate shape that satisfies the first performance requirement and the second performance requirement.

20. The computer-implemented method for designing 3-D structures of claim 11, the selecting step further comprising:
selecting a unit shape using a first solver;
selecting an internal geometry for the unit shape using a second solver;
selecting an internal geometry evolution for the unit shape and the internal geometry using a third solver.

21. The computer-implemented method for designing 3-D structures of claim 18, the selecting step further comprising: using a plurality of solvers to select a candidate geometry by identifying a solution shared by a majority of the plurality of solvers.
